(19) United States
(12) Patent Application Publication
(10) Pub. No.: US 2007/0287073 A1
(43) Pub. Date: Dec. 13, 2007

(54) Lithography systems and methods

(76) Inventor: Francis Goodwin, Halfmoon, NY (US)

Correspondence Address: SLATER & MATSIL LLP, 17950 PRESTON ROAD, SUITE 1000, DALLAS, TX, 75252, US

(21) Appl. No.: 11/448,455

(22) Filed: Jun. 7, 2006

(51) Int. Cl. G03B 27/54; G03F 1/00

(52) U.S. Cl. 430/5; 355/67

(57) ABSTRACT

Lithography systems and methods are disclosed. A preferred embodiment comprises a lithography system including a support for a substrate, a projection lens system, an illuminator adapted to direct light towards the support for the substrate through the projection lens system along an optical path, and at least one Fresnel element disposed in the optical path.

### TECHNICAL FIELD

The present invention relates generally to the fabrication of semiconductor devices, and more particularly to lithography systems and methods for patterning material layers of semiconductor devices.

### BACKGROUND

Generally, semiconductor devices are used in a variety of electronic applications, such as computers, cellular phones, personal computing devices, and many other applications. Home, industrial, and automotive devices that in the past comprised only mechanical components now have electronic parts that require semiconductor devices, for example.

Semiconductor devices are manufactured by depositing many different types of material layers over a semiconductor workpiece, wafer, or substrate, and patterning the various material layers using lithography. The material layers typically comprise thin films of conductive, semiconductive, and insulating materials that are patterned and etched to form integrated circuits (ICs). There may be a plurality of transistors, memory devices, switches, conductive lines, diodes, capacitors, logic circuits, and other electronic components formed on a single die or chip, for example.

Optical photolithography involves projecting or transmitting light through a pattern comprised of optically opaque or translucent areas and optically clear or transparent areas on a mask or reticle. For many years in the semiconductor industry, optical lithography techniques such as contact printing, proximity printing, and projection printing have been used to pattern material layers of integrated circuits. Lens projection systems and transmission lithography masks are used for patterning, wherein light is passed through the lithography mask to impinge upon a photosensitive material layer disposed on semiconductor wafer or workpiece. After development, the photosensitive material layer is then used as a mask to pattern an underlying material layer. In some lithography systems, such as extreme ultraviolet (EUV) lithography systems, reflective lenses and masks are used to pattern a photosensitive material layer disposed on a substrate, for example.

There is a trend in the semiconductor industry towards scaling down the size of integrated circuits, to meet the demands of increased performance and smaller device size. As features of semiconductor devices become smaller, it becomes more difficult to pattern the various material layers because of diffraction and other effects that occur during the lithography process. In particular, lithography techniques used to pattern the various material layers become challenging as device features shrink.

Thus, what are needed in the art are improved lithography systems and methods for patterning and forming material layers of semiconductor devices.

What are also needed in the art are improved methods of testing and quantifying the performance of lithography systems.

### SUMMARY OF THE INVENTION

These and other problems are generally solved or circumvented, and technical advantages are generally achieved, by preferred embodiments of the present invention, which provide novel lithography systems and methods, wherein at least one Fresnel element is placed in the optical path of the lithography system.

In accordance with a preferred embodiment of the present invention, a lithography system includes a support for a substrate, a projection lens system, an illuminator adapted to direct light towards the support for the substrate through the projection lens system along an optical path, and at least one Fresnel element disposed in the optical path.

The foregoing has outlined rather broadly the features and technical advantages of embodiments of the present invention in order that the detailed description of the invention that follows may be better understood. Additional features and advantages of embodiments of the invention will be described hereinafter, which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1A shows a prior art lithography system, illustrating that the entrance pupil of the projection lens system limits the number of orders of the reticle image collected, wherein the depth of focus (DOF) of the aerial image is small and the numerical aperture (NA) is large;

FIG. 1B shows a more detailed view of the orders collected by the entrance pupil of the projection lens system shown in FIG. 1A;

FIG. 2A shows a prior art lithography system, wherein the DOF of the aerial image is large and the NA is small;

FIG. 2B shows a more detailed view of the orders collected by the entrance pupil of the projection lens system shown in FIG. 2A;

FIG. 3A shows a prior art lithography system, wherein the DOF of the aerial image is small and the degree of coherence σ is low;

FIG. 3B shows a more detailed view of the orders collected by the entrance pupil of the projection lens system shown in FIG. 3A;

FIG. 4A shows a prior art lithography system, wherein the DOF of the aerial image is large and the degree of coherence σ is high;

FIG. 4B shows a more detailed view of the orders collected by the entrance pupil of the projection lens system shown in FIG. 4A;

FIG. 5 shows a prior art method of using a pinhole reticle to resolve an image of illuminated light from the illuminator at the entrance pupil onto a wafer to test the alignment of various elements of the illuminator and the accuracy of the illumination settings;

FIG. 6 illustrates a prior art lithography system using a pinhole reticle wherein an optimal focal plane P′ and focal range for imaging of the source is within the range of movement for the wafer stage, in non-EUV lithography systems;

FIG. 7 shows a perspective view of a novel Fresnel element comprising a plurality of concentric rings that is used for metrology of an illuminator of a lithography system in accordance with a preferred embodiment of the present invention;

FIG. 8 shows a side view of the Fresnel element shown in FIG. 7;

FIG. 9 illustrates a lithography system utilizing a reticle comprising a Fresnel element for metrology of the illuminator in accordance with an embodiment of the present invention, wherein the Fresnel element reduces the focal length to f₃;

FIG. 10 shows a perspective view of a test reticle including a single Fresnel lens in accordance with a preferred embodiment of the present invention;

FIG. 11 shows a perspective view of a test reticle including an array of a plurality of Fresnel lenses in accordance with another preferred embodiment of the present invention;

FIG. 12 shows an image of a light source resolved on a layer of photoresist in accordance with an embodiment of the invention using the metrology methods described herein and using conventional illumination;

FIG. 13 shows an image resolved on a layer of photoresist in accordance with another embodiment of the invention, wherein annular illumination is used;

FIG. 14 shows an image resolved on a layer of photoresist in accordance with another embodiment of the invention, wherein quadrapole illumination is used;

FIG. 15 shows a perspective view of a Fresnel element comprising a Fresnel grating in accordance with another embodiment of the present invention;

FIG. 16 is a perspective view of two Fresnel gratings placed side-by-side which may be used to image a periodic pattern on a layer of photoresist, due the constructive and destructive interference caused by the Fresnel gratings;

FIG. 17 shows a lithography system including a reticle comprising a plurality of Fresnel gratings shown in FIG. 16 that may be used to manufacture a semiconductor device in accordance with an embodiment of the present invention;

FIG. 18 shows a semiconductor device having a layer of photoresist formed thereon that has been patterned using the reticle comprising the plurality of Fresnel gratings as shown in FIGS. 16 and 17; and

FIG. 19 shows the semiconductor device of FIG. 18 after the layer of photoresist has been used to pattern a material layer of the semiconductor device, forming sub-resolution features in the material layer.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that embodiments of the present invention provide many applicable inventive concepts that can be embodied in a wide variety of specific contexts. The specific embodiments discussed are merely illustrative of specific ways to make and use the invention, and do not limit the scope of the invention.

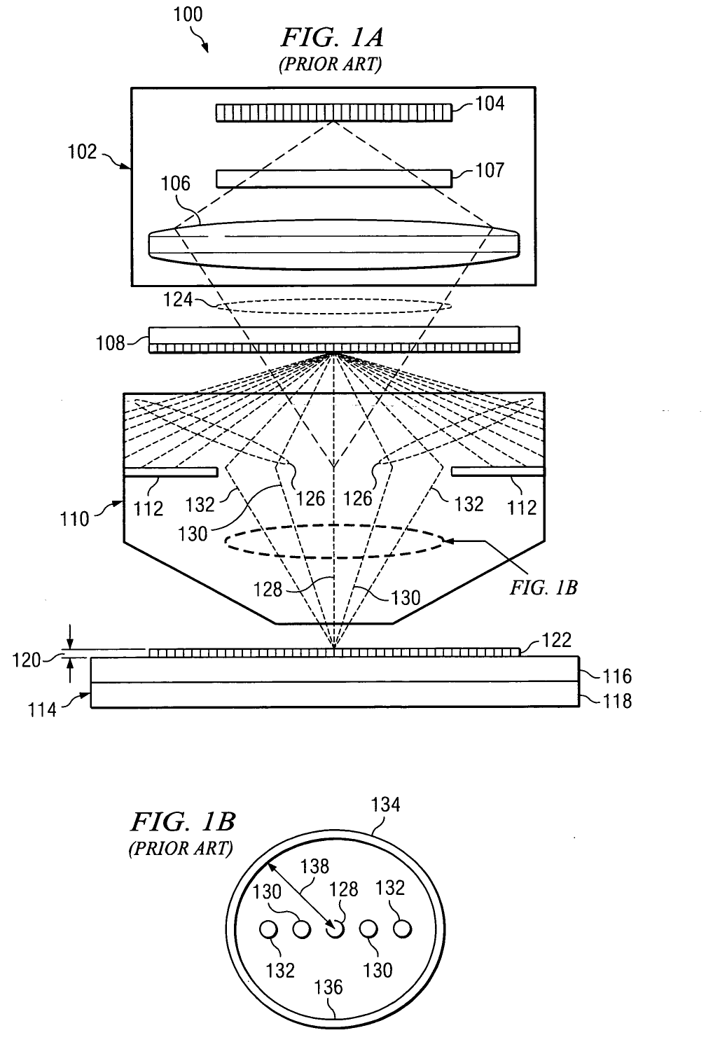

FIG. 1A shows a prior art lithography system 100 or microlithography exposure tool. The lithography system 100 includes an illuminator 102, a support or wafer stage (not shown) for a semiconductor device 114, and a projection lens system 110. The illuminator 102 comprises a light source 104, a condenser lens 106, and an integrator 107 disposed between the light source 104 and the condenser lens 106. The projection lens system 110 comprises a plurality of lenses (not shown) and includes an entrance pupil 112. The projection lens system 110 of the lithography system 100 projects an image from a mask or reticle 108 onto a layer of photoresist 116 of a semiconductor device 114. The semiconductor device 114 may include a workpiece, wafer, or substrate 118 having a material layer (not shown) disposed thereon that will be patterned using the layer of photoresist 116, for example. The layer of photoresist 116 is also referred to herein as a layer of photosensitive material 116, for example.

The quality of the images transferred from the reticle 108 to the semiconductor device 114 is a function of the photoresist 116 processing on the substrate 118 and by the performance of the illuminator 102 and the optics of the projection lens system 110 of the lithography system 100. In most advanced exposure or lithography systems 100, the imaging is controlled by adjustable optical characteristics, such as the numerical aperture (NA) of the projection lens system 110 and the partial or degree of coherence (σ) of the lithography system 100.

Light 124 is directed towards the semiconductor device 114 from the illuminator 102 through the reticle 108 and the projection lens system 110, as shown. Illumination of a reticle 108 comprising a pattern for lines and spaces generates an interference pattern. This interference pattern consists of a collection of diffracted light beams referred to as “orders,” as shown at 126. In a lithography system 100, the diffracted orders 126 (e.g., orders 128, 130, and 132) are collected and converged such that they recombine at the photoresist layer 116 on the device 114 to reproduce the reticle 108 image into the layer of photoresist 116, as shown at 122, which represents an aerial image of the reticle formed on the layer of photoresist 116.

For a perfect reproduction of the reticle 108 image, all of the orders 126 would need to be collected by the projection lens system 110, but due to physical constraints to the size of lenses of the projection lens system 110, only those orders 128, 130, and 132 traveling close to the optical axis are captured. The entrance pupil 112 of the projection lens system 110 limits the number of orders 128, 130, and 132 of the reticle 108 image collected. The entrance pupil 112 also controls the resolution of the optics of the projection lens system 110, as shown in FIG. 1A. FIG. 1B shows a more detailed view of the orders 128, 130 and 132, wherein 128 is the 0th order that passes straight through along the optical axis, wherein 130 are the first orders, and wherein 132 are the second orders, collected by the entrance pupil 112 of the projection lens system 110 shown in FIG. 1A. An entrance pupil 112 having a large NA 136 with a radius 138 and having a small depth of focus (DOF) is shown in FIG. 1B. The entrance pupil 112 is shown at 134 in FIG. 1B.

The size of the entrance pupil 112 influences the NA 136 and σ of the lithography system 100. For a reticle 108 image to resolve onto a substrate 118 coated with a layer of photoresist 116 (e.g., onto semiconductor device 114), the 0th order 128 and the first orders 130 must be captured. Any additional orders (such as the second orders 132 or other orders 126) collected assist in the enhancement of the resolution of the image 122 formed on the layer of photoresist 116. Thus, the angle of the orders is important to the quality of the exposure. The sine of the maximum possible angle that can be captured is referred to as the numerical aperture (NA). The resolution of the image 122 at the semiconductor device 114 increases linearly with increased NA, as expressed in Equation 1 below;

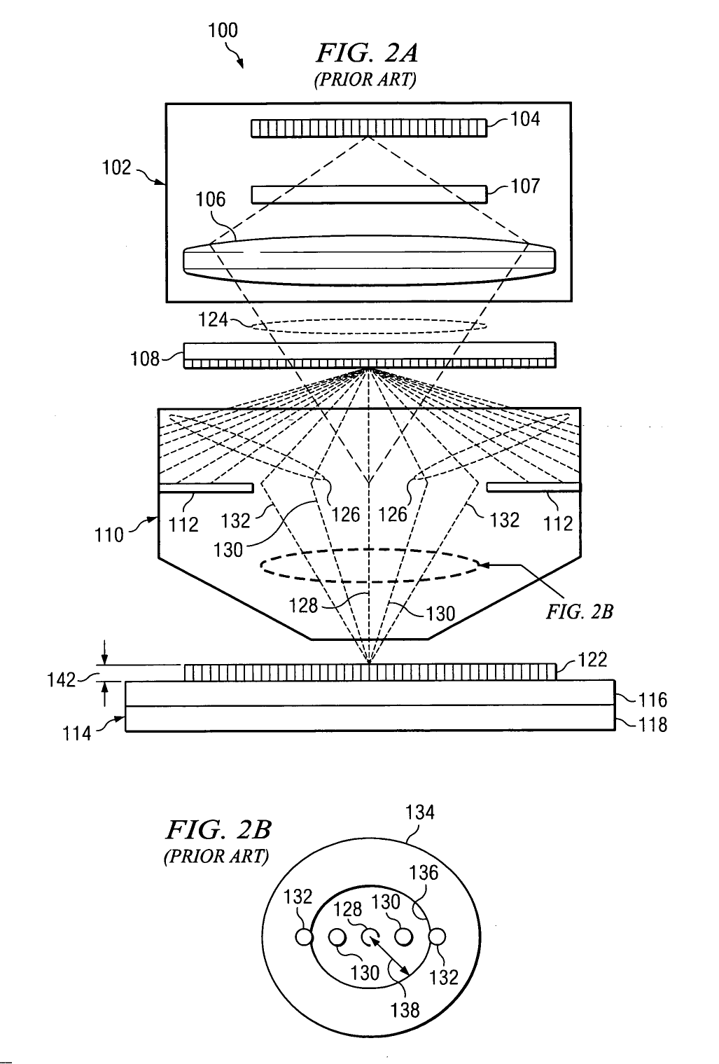

Res=kᵢ×λ/NA Equation 1

where Res is the resolution, k₁ is a first process factor which typically ranges from about 1.2 to 0.8 that accounts for enhance imaging techniques and optical effects from the projection lens system 110, λ is the wavelength of the light 124, and NA is the numerical aperture. However, an increased NA causes a strong reduction in the depth of focus (DOF), as shown by Equation 2 and in FIG. 1A at 120, FIG. 1B at 136, FIG. 2A at 142, and FIG. 2B at 136;

DOF=k₂×λ/NA² Equation 2

wherein k₂ is a second process factor which typically ranges from about 1.2 to 0.4 that accounts for enhanced imaging techniques and optical effects from the projection lens system 110.

For example, FIG. 1A shows a prior art lithography system 100 wherein the DOF 120 of the aerial image 122 is small, and FIG. 1B shows a more detailed view of the orders collected by the entrance pupil 112 of the projection lens system 110 shown in FIG. 1A, wherein the NA 136 is large. FIG. 2A shows a prior art lithography system 100 wherein the DOF 142 of the aerial image 122 is large, and FIG. 2B shows a more detailed view of the orders collected by the entrance pupil 112 of the projection lens system 110 shown in FIG. 2A, wherein the NA 136 is small. The radius 138 of the NA in FIG. 2B is smaller than the radius 138 of the NA 136 in FIG. 1B, indicating a smaller NA in FIG. 2B, for example.

When the illuminator 102 of the lithography system 100 illuminates the reticle 108, the projection lens system 110 projects the image of the reticle 108 onto the substrate 114. The illuminator 102 projects the image of the integrator 107 onto the entrance pupil 112 of the projection lens system using the condenser lens 106. This form of illumination is referred to as Kohler illumination. Each diffracted order 128, 130, and 132 from the reticle 108 image forms an image of the integrator 107 in the entrance pupil 112. The size of the images has an effect on the quality of the transferred reticle 108 image. The partial coherence or degree of coherence, σ (sigma), is a measure of this phenomenon, which can be determined using Equation 3.

$$σ = \frac{Diameter of integrated image in entrance pupil}{Diameter of entrance pupil} \qquad \text{Equation 3}$$

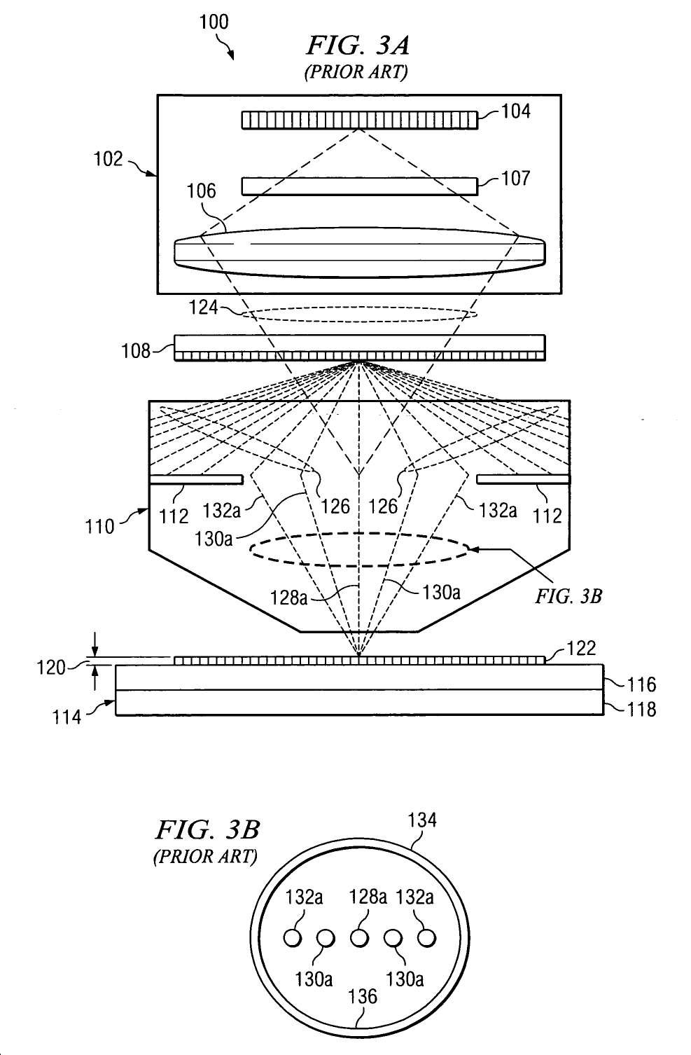

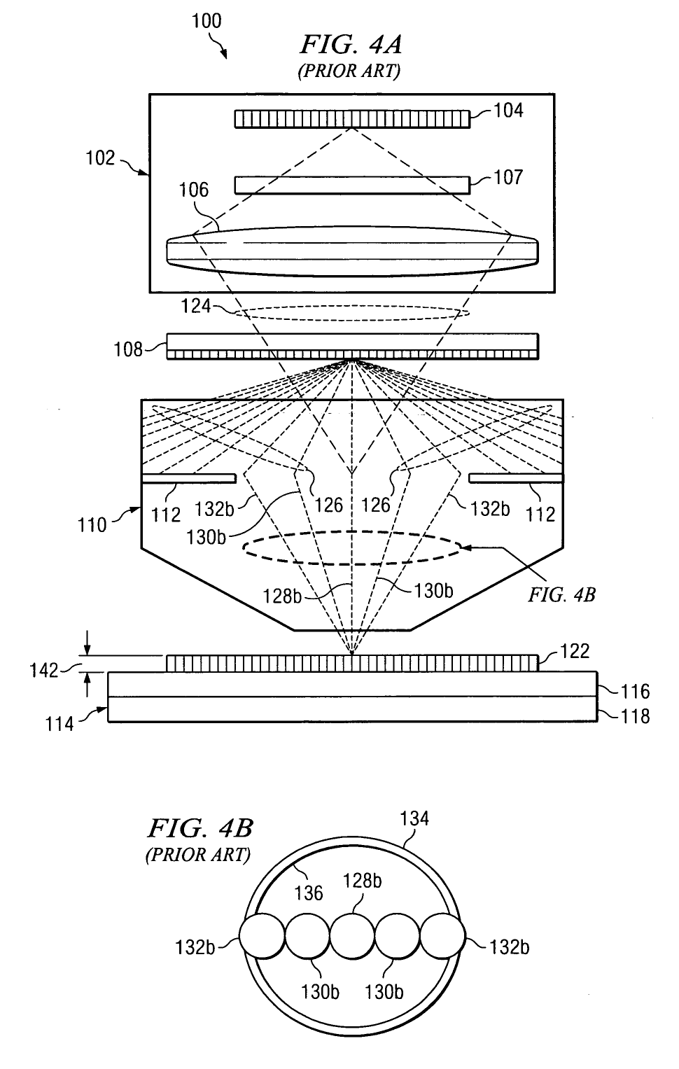

Low σ settings indicate that only a small part of the orders are passed through the entrance pupil 112, because a large portion of the diffracted orders are blocked. High σ values allow a larger portion of the orders to be delivered to the semiconductor device 114, as shown in FIGS. 3A, 3B, 4A, and 4B. For example, FIG. 3A shows a prior art lithography system 100 wherein the DOF 120 of the aerial image 122 is small and the degree of coherence σ is low, and FIG. 3B shows a more detailed view of the orders 128a, 130a, and 132a collected by the entrance pupil 112 of the projection lens system 110 shown in FIG. 3A. FIG. 4A shows a prior art lithography system 100 wherein the DOF 142 of the aerial image 122 is large and the degree of coherence σ is large, and FIG. 4B shows a more detailed view of the orders 128b, 130b, and 132b collected by the entrance pupil 112 of the projection lens system 110 shown in FIG. 4A. To change the size of the diffracted orders 128a, 130a, and 132a in FIG. 3B and diffracted orders 128b, 130b, and 132b in FIG. 4B, the effective diameter of the integrator 107 may be adjusted through the use of special optics or blades, for example, not shown. The NA 136 in both FIGS. 3B and 4B is large, for example.

The shape of the illumination and the size and position in the entrance pupil 112 of the projection lens system 110 has a significant impact on the quality of the image transferred from the reticle 108 to a photoresist-coated device 114. Accurate projection of the integrator 107 and source 104 image onto the entrance pupil 112 is critical in lithographic imaging. The source 104 should be symmetrical about the optical axis of the projection lens system 110 and should be fixed as a function of lens position. Poor symmetry of the source 104 degrades the telecentricity of the projection lens system 110. Variations in the source image with field position results in non-uniform partial coherence across the projection lens system 110, for example.

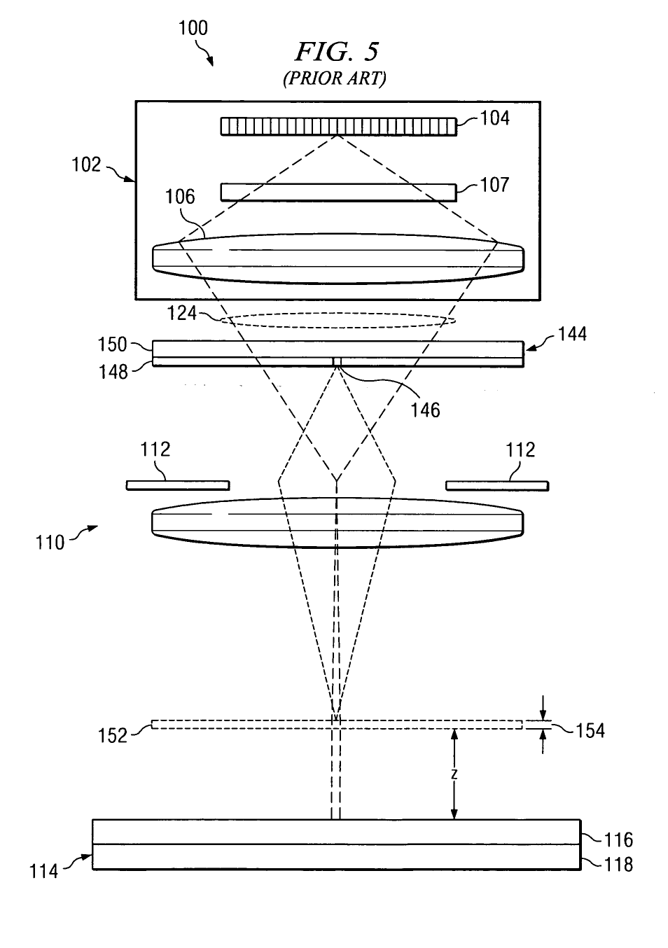

On an exposure tool or lithography system 100, a measure of these parameters, e.g., pupil measurement, is often obtained using a pinhole reticle 144, sometimes referred to as a “pinhole camera,” using the pinhole reticle 144 to image the source 104 of the illuminator 102 onto a photoresist-coated substrate 118, as shown in FIG. 5. A prior art method is shown wherein a pinhole reticle 144 is used to resolve an image of illuminated light 124 from the illuminator 102 at the entrance pupil 112 onto a semiconductor device 114 in order to test the alignment of various elements 104, 107, and 106 and parameters of the illuminator 102. The image formed on the layer of photoresist 116 using the metrology methods shown is an image of the source 104. The image of the source resolved in the photoresist 116 may be examined to determine if the source 104 or other element of the illuminator 102 requires adjusting, e.g., aligning, and determine the accuracy of the illumination settings.

The pinhole camera typically comprises a reticle 144 with a small pinhole 146 in an opaque background. The reticle 144 may comprise a transparent material 150 such as quartz or glass bonded or attached to an opaque material 148 comprising chrome or other material that has been patterned with the pinhole 146, as shown in FIG. 5. An aerial image 152 of the pinhole 146 is formed at the focal plane of the projection lens system 110 above the wafer (e.g., the semiconductor device 114) within the focus range of the exposure tool 100. The aerial image 152 functions as a wafer level pinhole lens. Moving the device 114 away from optimum focus, the “wafer level pinhole lens” acts as a camera and at a defocus distance z from the aerial image 152 to the device 114, a low resolution image of the illumination at the entrance pupil 112 can be resolved onto the device 114, as shown in FIG. 5. The aerial image 152 has a DOF 154. At the defocus length z, the NA, sigma, and telecentricity of the illumination can be obtained by analyzing the image formed within the layer of photoresist 116 on the substrate 118, e.g., on the semiconductor device 114.

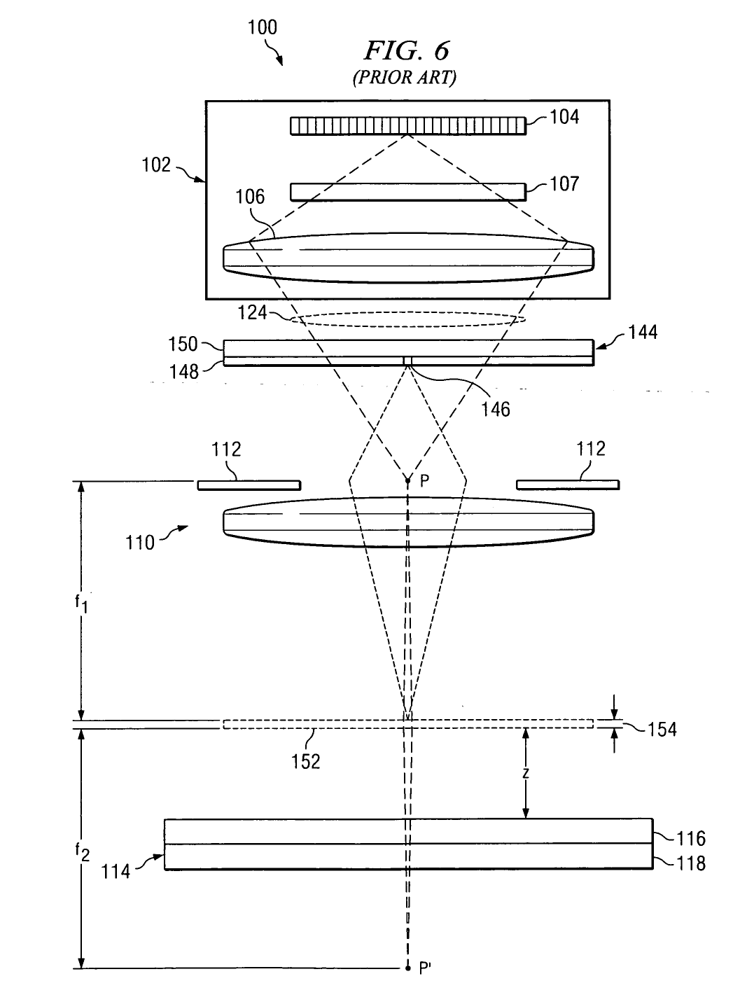

In deep ultraviolet (DUV) exposure tools with a high NA and σ setting, the pin-hole reticle technique produces a low resolution image of the illumination which is sufficient to measure the NA, sigma, and telecentricity of the illuminator 102. Ideally, the device 114 should be placed at the point of second focus or image focus P′ where the focal lengths f₁ and f₂ are equal, rather than at the defocus length z, as shown in prior art FIG. 6. At the second focus position P′, the image of the source 104 will be fully in focus, whereas at the defocus length z, the image of the source 104 is partially defocused, for example. Again, an aerial image 152 of the pinhole reticle 144 is formed. Since the depth of focus for the pinhole lens is large, the image of the illuminator 102 is resolved within the available travel distance of the wafer stage (e.g., the support for the semiconductor device 114, not shown) of lithography systems 100 such as DUV tools, and well away from optimum focus.

Thus, in prior art non-EUV lithography systems 100, techniques of metrology for illuminators 102 utilize a pinhole 146 on the backside of a reticle 144 which is imaged onto a semiconductor device 114. The backside of the reticle 144 is used to adjust for the extended focal length induced by the pinhole 146 lens. For exposure tools with a high numerical (NA), the thickness of the reticle 144 is sufficient to compensate for the increased focal length.

However, EUV lithography systems use reflective optics and masks to produce device images. The lens elements in EUV lithography systems are manufactured with reflecting mirrors, which restrict the maximum NA and σ settings to low values. This increases the focus range of the exposure tool and the point of image focus of the illuminator. For an EUV lithography system with a low NA, such as an EUV lithography scanner, the focal lengths are too large to compensate for within the limited travel lengths of the reticle and wafer stage of the scanner, so it is not possible to resolve an image of the illuminator on the device using a pinhole reticle. Therefore, prior art pinhole lens techniques may not be used to resolve the positioning and uniformity of the illumination within the entrance pupil of the reduction lens in some lithography systems, such as EUV lithography systems.

For example, in an EUV lithography system, because the NA and σ values are reduced, the point of image focus moves further away from the lens and the allowed wafer stage movement (e.g., the stage supporting the semiconductor device 114) is no longer sufficient to capture the image. The stage or support for the semiconductor device 114 may only be moved away from the reticle 144 by a predetermined distance, for example. The result is that the allowed range of motion of the reticle stage and the wafer stage of the lithography system is not sufficient to support resolution of the illuminator at the wafer level, so that a pinhole reticle cannot be used for metrology of the illuminator.

In the past, Fresnel lenses, named after the inventor thereof, Augustin-Jean Fresnel, were often used as lenses in lighthouses. Fresnel lenses focus light towards the center of the path of light, making light emitting from a light source visible over longer distances. Fresnel lenses are used in other applications, such as in lighting instruments for theatre and motion pictures and as magnification lenses in large automobiles or recreational vehicles (RVs), as examples.

Embodiments of the present invention achieve technical advantages by using a Fresnel element comprising a plurality of Fresnel zones in the optical path of light of an optical lithography system. In some embodiments, a Fresnel lens is used to image the pupil fill of an exposure tool. The Fresnel lens may be used for metrology of an illuminator of a lithography system. The Fresnel lens may be used to produce pupil diagrams of photolithography exposure systems. In other embodiments, a plurality of Fresnel gratings may be used for forming periodic patterns on material layers of a semiconductor device.

The present invention will be described with respect to preferred embodiments in a specific context, namely for metrology of illuminators used in lithography systems. Embodiments of the invention may also be used, for example, implemented in a lithography system used to pattern material layers of semiconductor devices, to be described further herein. Embodiments of the invention may also be applied, however, to other lithography applications, for example.

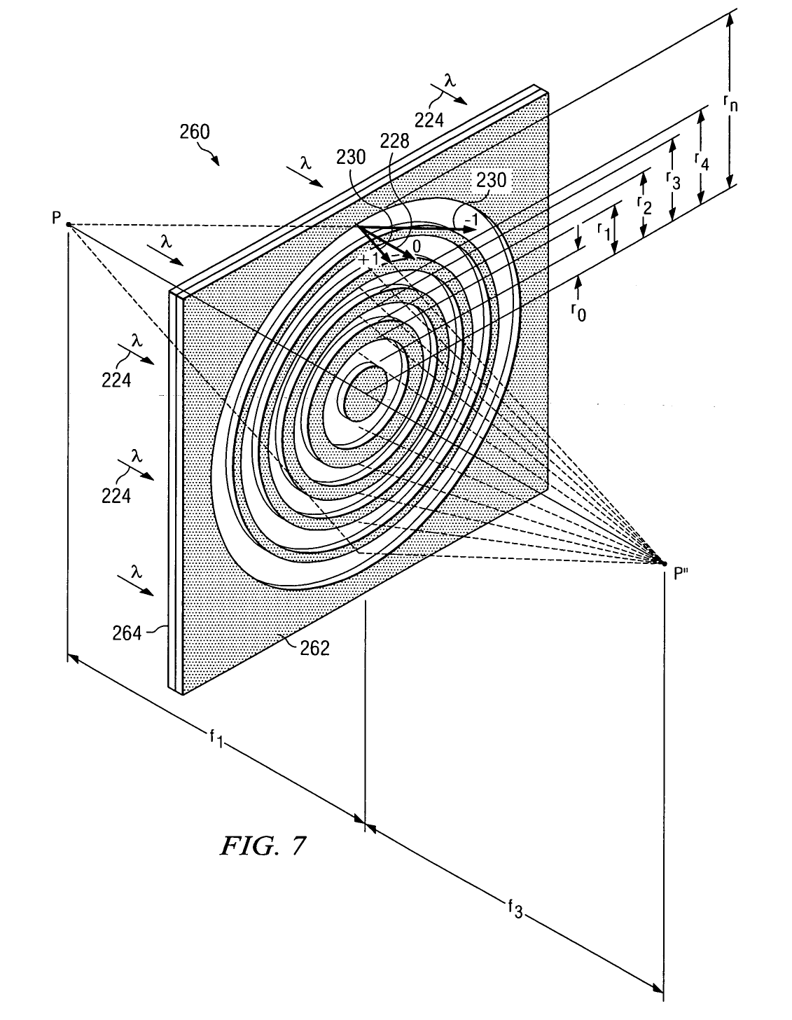

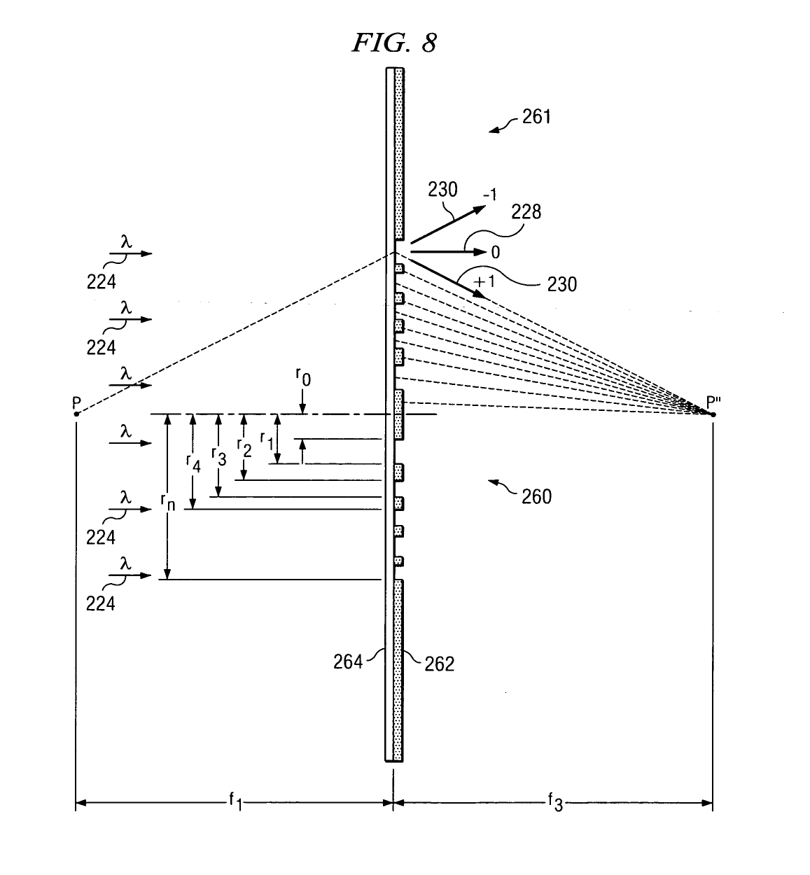

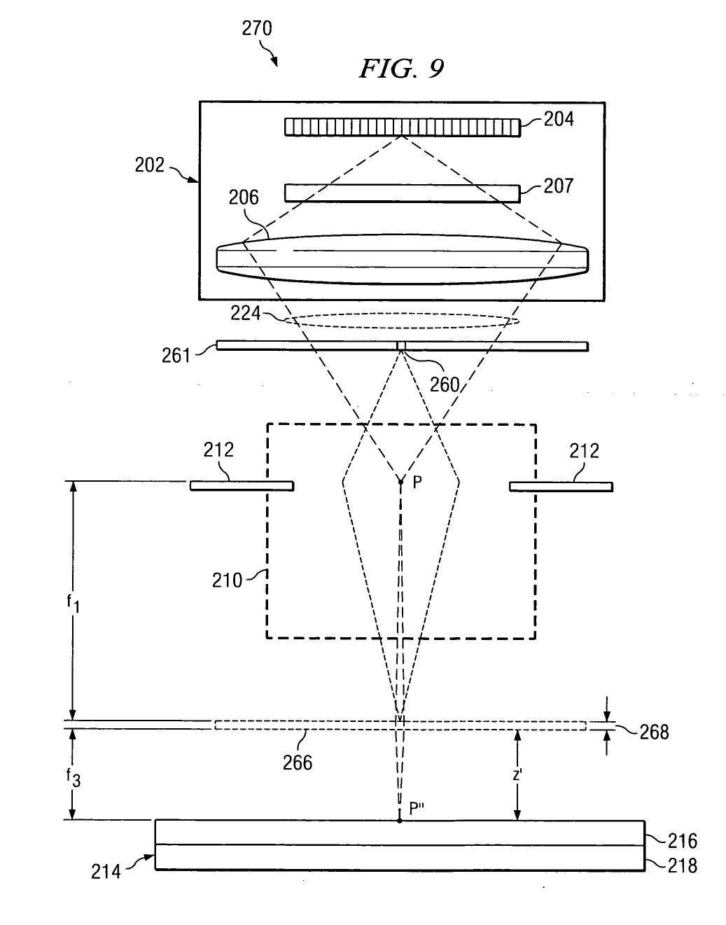

FIG. 7 shows a perspective view of a novel Fresnel element 260 that is used for metrology of an illuminator of a lithography system in accordance with a preferred embodiment of the present invention. FIG. 8 shows a side view of the Fresnel element 260 shown in FIG. 7. A method of using a test reticle 261 comprising a Fresnel element 260 for metrology of an illuminator 202 of a lithography system 270 is shown in FIG. 9.

Referring to FIGS. 7 and 8, the Fresnel element 260 in accordance with a preferred embodiment of the present invention comprises a plurality of concentric circles or ring-shaped apertures formed in an opaque or optically light-absorbing material 262. The concentric rings comprise Fresnel zones that are adapted to create constructive and destructive interference of light. The opaque or light-absorbing material 262 may be attached or bonded to a transparent or a light-reflecting material 264, as shown. The Fresnel element 260 preferably comprises a Fresnel lens that is implemented in an otherwise substantially opaque or light-absorbing reticle 261, for example.

In implementing a Fresnel lens 260 onto a reticle or mask 261, either the even or odd diffraction orders of light are blocked by the Fresnel lens 260, for example. The diffraction orders 228, a zero order (0), and 230, a first order (−1 and +1), are shown, for example. By blocking the even or odd diffraction orders, only constructive interference of the remaining order results, which results in discrete steps in focal length. These discrete lengths can be tailored with the designed radius r₀ to rₙ and rings (e.g., the concentric circles) of the Fresnel lens 260. Thus, a Fresnel lens 260 can be designed that is capable of imaging the source 204 of an illuminator 202 of a lithography system 270 onto a layer of photoresist 216 within the restricted range of motion of the reticle 261 and wafer 214 stages. The Fresnel lens 260 is thus effective for metrology of lithography systems that utilize both refractive and reflective optics and for lenses with high and low NAs, such as EUV lithography systems.

The Fresnel lens 260 comprises a circularly symmetric diffraction grating composed of alternating opaque or light-absorbing and transparent or light-reflecting zones. Each transparent or reflective ring of the Fresnel lens 260 has a different width than an adjacent transparent or reflective ring, for example. As light 224 impinges upon the Fresnel lens 260 at a wavelength λ, diffracted waves are focused to multiple focal points. In FIG. 7, for example, the first order diffraction waves 230 are focused to the primary or the first-order focal point P″. Advantageously, the focal point P″ may comprise a focal length f₃ that is shorter than focal length f₁, due to the effect of the Fresnel lens 260, to be described further herein.

In one embodiment, the Fresnel lens 260 is positioned on an otherwise opaque reticle 261. The Fresnel lens 260 is placed in the optical path and is used to shorten the focal plane P″, bringing the focal plane P″ of the entrance pupil to the device 114 level.

The Fresnel element 260 shown in FIGS. 7 and 8 comprises a Fresnel lens which comprises a circularly symmetric diffraction grating comprised of alternating opaque and transparent zones for use in systems with refracting optics, or absorbing and reflecting materials for use in systems using fully reflecting optics. Under plane wave illumination, the Fresnel lens 260 diffracts the incident waves and focuses these waves to different locations or different focal points. The first-order diffraction waves 230, which have the highest intensity except for the zeroth-order plane wave 228, are focused to a point referred as the primary or the first-order focal point P″. If a right triangle is drawn that has the primary focal length f as one side and the radius of any zone rₙ as a second side, Equation 4 describes the relationship of the variables for constructive interference in the first-order to occur at the point f (e.g., wherein f in Equation 4 is represented by f₃ in FIGS. 7 and 8):

f²+rₙ²=(f+nλ/2)²; Equation 4

wherein r is the radius of the each ring, n is the number of rings, and λ is the wavelength of light 224.

Upon expansion and consolidation of like terms, Equation 4 can be expressed as Equation 5 below.

rₙ²=nλf+n²λ²/4 Equation 5

The term n²λ²/4 represents spherical aberration, which can be ignored for f>>nλ2. Then, Equation 5 can be simplified to Equation 6 below.

rₙ²≅nλf Equation 6

Equation 6 shows that the first-order focus is achieved as successive zones increase in radius by \sqrt{n}, providing the desired prescription by which the radial grating period must decrease in order to provide common focus.

In FIGS. 7 and 8, radius r₀ is a radius measured from about ¼ from the edge of central circular region of the Fresnel lens to a central point inside the concentric rings. Radius r₁ is a radius from a center of a ring-shaped aperture formed in the opaque or light-absorbing material 262 to the central point of the Fresnel lens. Radius r₂ is a radius from a center of a ring of the material 262 to the central point of the Fresnel les. The other radii r₃, r₄, and rₙ are similarly defined. There may be a total of 10 or more ring-shaped apertures formed in the opaque or light-absorbing material 262, for example, although other numbers of rings may also be used.

The Fresnel lens 260 is preferably used as a camera, in one embodiment. For example, a Fresnel lens 260 can be implemented on a lithography reticle 261, which is also referred to herein as a Fresnel zone-plate lens, for example. As the focus of a Fresnel zone-plate lens can be controlled by the radial gratings of the lens, a Fresnel zone-plate lens can be designed to image within a limited focus range. This is accomplished by replacing the focal length parameter f in Equation 6 with a weighted average of the focal length between the entrance pupil and the aerial image of the lens f₁ and the focal length between the wafer plane and the lens aerial image f₃ in FIG. 9. Equation 6 can then be represented as Equation 7:

$${r}_{n}^{2} ≅ n λ ( \frac{{f}_{1} \times {f}_{3}}{{f}_{1} + {f}_{3}} ) \qquad \text{Equation 7}$$

and as f₃ is much larger than f₁, Equation 7 can be expressed as Equation 8:

rₙ²≅nλf₃ Equation 8

Since, for this purpose, the radius r of the Fresnel lens 260 is dependant on the distance between the aerial image 266 and the wafer stage (not shown; the wafer stage or support would be disposed immediately beneath the workpiece or wafer 218 of the lithography system 270 shown in FIG. 9), a Fresnel lens 260 can be designed to focus an image of the light 224 at the entrance pupil 212 of a projection lens system 210 well within the restricted range of movement of the wafer stage or support for a semiconductor device 214.

FIG. 9 illustrates a lithography system 270 utilizing a test reticle 261 comprising a Fresnel element 260 for metrology of the illuminator 202, wherein the use of the Fresnel element 260 results in a reduction of the focal length f₃. Note that like numerals are used in FIG. 9 as were used in the previous figures, and to avoid repetition, all of the elements are not described in detail again herein. Rather, similar materials x02, x04, x06, x07, etc . . . are preferably used for the various elements shown as were described for the previous figures, where x=1 in FIGS. 1A through 6, and x=2 in FIG. 9.

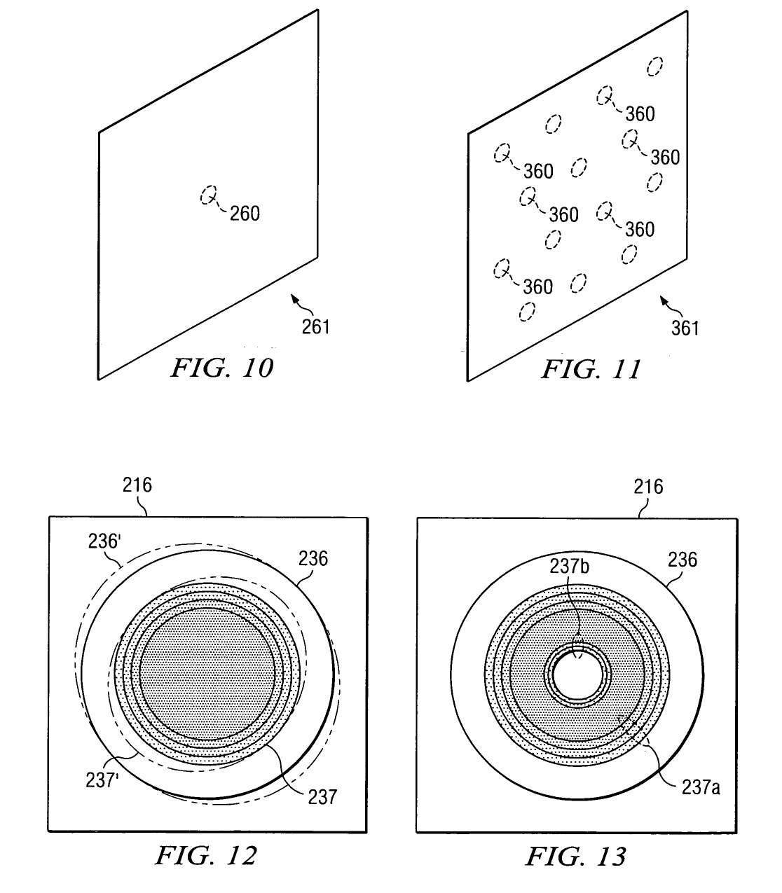

In FIG. 9, the test reticle 261 includes a Fresnel element 260 comprising a Fresnel lens, as shown in FIGS. 7 and 8. FIG. 10 shows a perspective view of a test reticle 261 including a single Fresnel lens 260 in accordance with a preferred embodiment of the present invention. Alternatively, a test reticle 361 may comprise an array of a plurality of Fresnel lenses 360, as shown in FIG. 11 in a perspective view, in accordance with another preferred embodiment of the present invention.

The test reticles 261 and 361 shown in FIGS. 10 and 11 may comprise an overall length and width of about 6″, for example. The Fresnel lenses 260 and 360 may comprise a diameter of about 9 to 26 mm, as examples, for a stepper having an exposure slit of about 5 to 9 mm, as an example, although alternatively, the Fresnel lenses 260 and 360 may comprise other dimensions. The array of Fresnel lenses 360 shown in FIG. 11 may comprise Fresnel lenses 360 that are spaced apart by several μm, for example.

Referring again to FIG. 9, the source 204 produces light 224 having a wavelength λ (which is about 13.5 nm for an EUV lithography system, although other wavelengths λ may also be used) which passes through the integrator 207 and the condenser lens 206 of the illuminator 202. The light 224 is directed by the condenser lens 206 to the test reticle 261 to the entrance pupil 212 of the projection lens system 210 at a point P having a focal length f₁ away from an aerial image 266 of the test reticle 261, wherein the aerial image 266 has a DOF of 268. The substrate 218 having a layer of photoresist 216 disposed thereon (e.g., a semiconductor device 214) may be moved to a distance P″ that has a focal point f₃ away from the aerial image 266 of the test reticle 261, as shown. Thus, the image of the source 204 can be imaged on the layer of photoresist 216, e.g., the defocus length z′ may be made equal to P″ by positioning the device 214 at the appropriate distance away from the illuminator 202. Because of the use of the Fresnel lens 260 on the test reticle 261, focal length f₃ is decreased, and advantageously, focal length f₃ may be less than focal length f₁.

After an image of the illuminator 202 (e.g., an image of the source 204) is formed on the layer of photoresist 216, it is developed, and the image formed on the layer of photoresist 216 is then examined and analyzed for metrology of the components, elements, and parameters of the illuminator 202. For example, FIG. 12 shows an image resolved on a layer of photoresist 216 of a semiconductor device 214 such as the device 214 shown in FIG. 9 in accordance with an embodiment of the invention, wherein the illuminator 202 is set at a conventional illumination setting, e.g., using a single beam of light 224. The inner ring or circle 237 is the partial coherence setting of the source 204 imaged into the resist. The outer ring or circle 236 represents the NA, and is indicative of the NA setting of the source 204.

The NA 236 should be circular rather than elliptical, as shown in phantom at 236′. If the NA 236′ is elliptical, then the condenser lens 206 may be skewed and may require adjusting, for example. The condenser lens 206 columnates the light 224 and directs it to the reticle 261. Therefore, the light from condenser lens 206 should be of uniform intensity across the reticle 261 and must be centered along the optical axis, for example.

The inner ring 237 should be circular and should be centered within the NA 236. If the inner ring 237′ are skewed more towards one side of the NA 236, then another element or component within the illuminator 202 needs to be adjusted. For example, the telecentricity of the condenser lens 206 may require adjusting, e.g., by centering it along the optical axis, to center partial coherence setting 237 within the NA 236. The inner ring 237 should also be circular rather than elliptical, as shown in phantom at 237′. If the inner ring 237′ is elliptical, then the source 204, condenser lens 206, or the integrator 207 may need to be aligned or repositioned, as examples.

Furthermore, the intensity of the images formed in the resist 216 indicate that the intensity level of the illumination may need to be adjusted, for example.

FIG. 13 shows an image resolved on a layer of photoresist 216 in accordance with another embodiment of the invention, wherein annular illumination is used to illuminate the resist 216. In annular illumination, the source emits an annular or ring-shaped beam of light, which is imaged on the photoresist 216, as shown at 237a and 237b, which are the inner and outer partial coherence settings imaged on the layer of photoresist 216, respectively. Again the outer ring 236 is the NA setting imaged onto the layer of photoresist 216. If either of the rings 237a or 237b are elliptical or uncentered within the NA 236, this indicates that an element or component within the illuminator 202 needs to be adjusted, such as the positioning or alignment of the integrator 207, the condenser lens 206, or the source 202, for example.

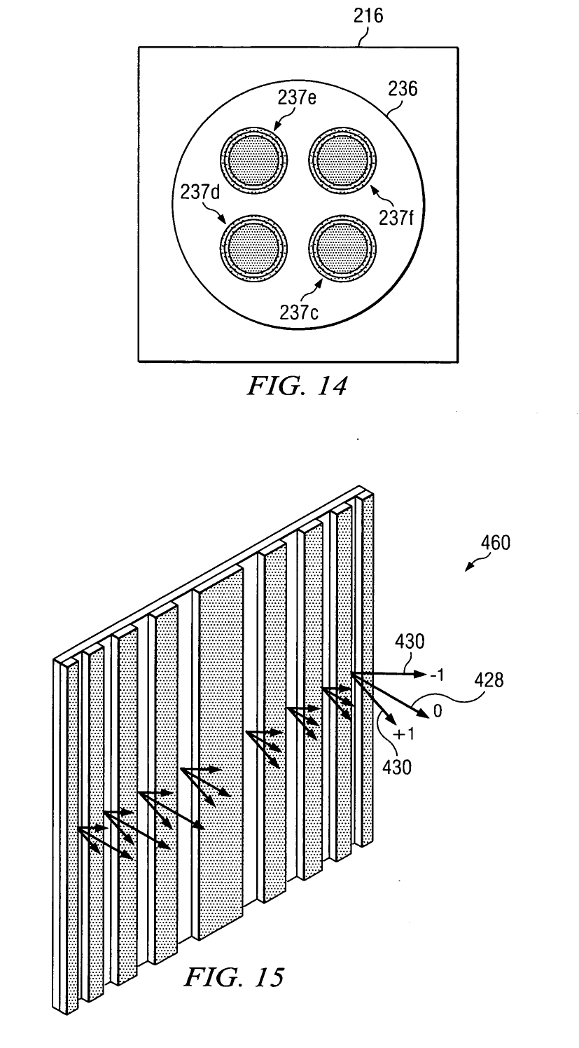

FIG. 14 shows an image resolved on a layer of photoresist 216 in accordance with another embodiment of the invention, wherein quadrapole illumination is used to illuminate the resist 216. In quadrapole illumination, the source emits four beams of light, which is imaged on the photoresist 216, as shown at 237c, 237d, 237e, and 237f, which are the partial coherence settings imaged on the layer of photoresist 216, respectively. Again, the outer ring 236 is the NA setting imaged onto the layer of photoresist 216. If either of the rings 237c, 237d, 237e, and 237f are elliptical or uncentered within the NA 236, this indicates that an element or component within the illuminator 202 needs to be adjusted, such as the positioning or alignment of the integrator 207, the condenser lens 206, or the source 202, for example.

Note that in FIGS. 12, 13, and 14, conventional, annular, and quadrapole illumination is used to form an image on the layer of photosensitive material 216 of a semiconductor device 214, respectively, e.g., wherein the illuminator 202 is placed on the particular settings. Alternatively, other settings of the illuminator 202 may be used for metrology of the illuminator 202 using the novel Fresnel lenses 260 and 360 described herein, e.g., such as dipole or other illumination settings, as examples. The image formed on a layer of photosensitive material 216 would appear differently than is shown in FIGS. 12, 13, and 14 for other types of illumination, but the images formed on the layer of photosensitive material 216 may also be examined and analyzed to determine if components of the illuminator 202 are aligned properly, or if the precision of the illuminator settings is acceptable, for example.

Referring again to FIG. 9, in accordance with a preferred embodiment of the present invention, a method of metrology for an illuminator 202 of a lithography system 280 includes providing a workpiece 218, the workpiece 218 including a layer of photoresist 216 formed thereon, and disposing a test reticle 261 or 361 (see FIG. 11) having a Fresnel element 260 or 360 disposed thereon between the illuminator 202 and a projection lens system 210 of the lithography system 280. The method includes illuminating the layer of photoresist 216 with light 224 from the illuminator 202, developing the layer of photoresist 216, and examining the layer of photoresist 216 to determine if a component of the lithography system 270 requires adjusting. For example, an image formed on the layer of photoresist 216 may comprise at least one circular shape 237, 237a, 237b, 237c, 237d, 237e, or 237f (see FIGS. 12 through 14) corresponding to the shape of a source 204 of the illuminator 202, e.g., indicating the partial coherence setting of the illuminator 202, and a ring 236 proximate the at least one circular shape 237, 237a, 237b, 237c, 237d, 237e, or 237f corresponding to a numerical aperture of the illuminator 202. Referring again to FIG. 9, the illuminator 202 may comprise a source 204, an integrator 207, and a condenser lens 206, and the method may further include adjusting the source 204, integrator 207, and/or condenser lens 206 after examining the layer of photoresist 216 of the semiconductor device 214, or adjusting an illumination setting of the illuminator 202.

Next, using a Fresnel element 460 in a lithography system 480 for patterning features of a semiconductor substrate 414 will be described, with reference to FIGS. 15 through 19. Like numerals are used for the various elements in FIGS. 15 through 19 that were used for the previous figures, and to avoid repetition, each reference number shown in FIGS. 15 through 19 is not described again in detail herein.

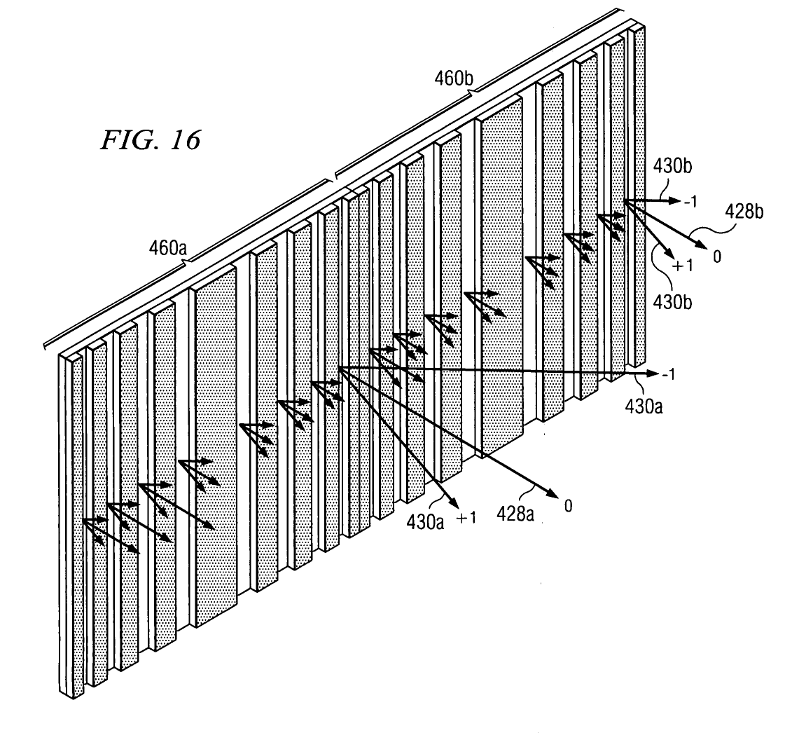

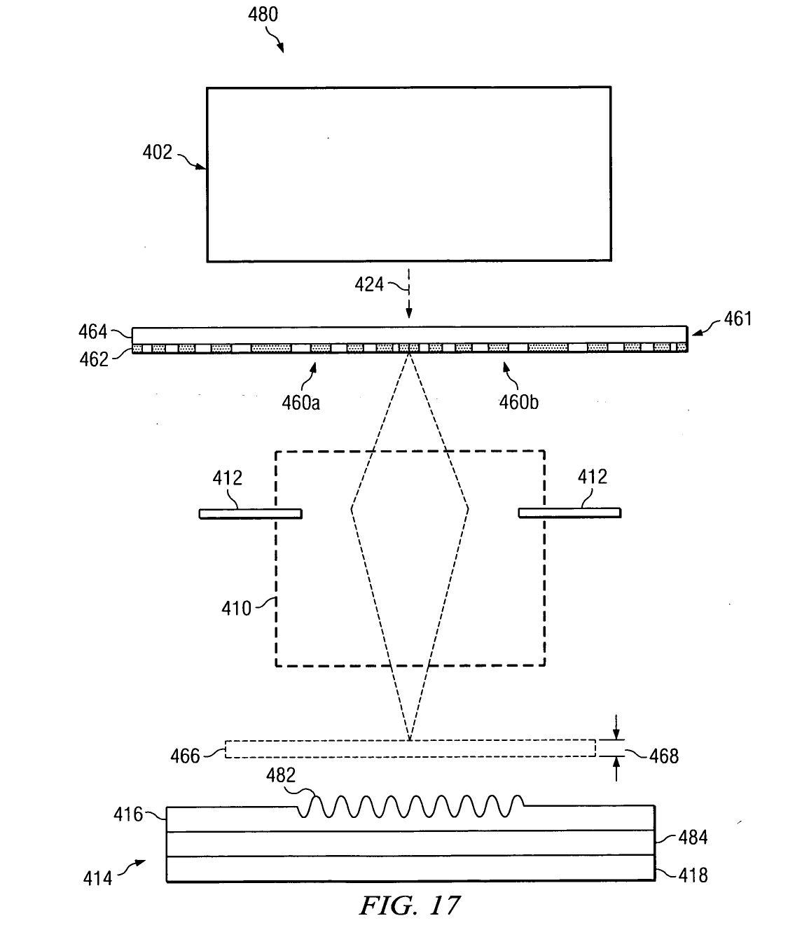

In this embodiment, the Fresnel element 460 preferably comprises a plurality of Fresnel zones comprising a Fresnel grating. The Fresnel grating 460 comprising a plurality of vertically-extending lines having varying widths, as shown in FIG. 15 in a perspective view. The Fresnel grating 460 causes light to diffract into 0th order 428 (0) and first orders 430 (+1 and −1), as shown. Two Fresnel gratings 460a and 460b are preferably placed proximate one another, and are more preferably placed side-by-side directly adjacent and abutting one another on a reticle or lithography mask 461, as shown in FIG. 16 in a perspective view and in FIG. 17.

The two Fresnel gratings 460a and 460b placed side-by-side may be used to image a periodic pattern on a layer of photoresist 416, due the constructive and destructive interference caused by the Fresnel gratings 460a and 460b. The diffracted orders 428a and 428b, and 430a and 430b, respectively, of the adjacent Fresnel gratings 460a and 460b, constructively and destructively interfere with one another, for example. The Fresnel gratings 460a and 460b preferably comprise alternating apertures and opaque material or light-reflecting and light-absorbing material having varying widths close to the wavelength of the lithography system 480, e.g., close to about 13.5 nm in an EUV lithography system, for example.

FIG. 17 shows a lithography system 480 including a reticle 461 comprising a plurality of Fresnel gratings 460a and 460b shown in FIG. 16. The first Fresnel grating 460a and the second Fresnel grating 460b are adapted to produce a periodic pattern 482 on the layer of photosensitive material 416 of the semiconductor device 414. More than two Fresnel gratings 460a and 460b may be present on a reticle 461, not shown, to form a plurality of periodic patterns in more than one location on a semiconductor device 414, for example.

Note that due to the constructive and destructive interference of the two adjacent Fresnel gratings 460a and 460b, the periodic pattern 482 does not comprise the same pattern as the Fresnel grating 460a and 460b patterns. The Fresnel grating 460a and 460b patterns are non-periodic, having uneven lines and spaces, e.g., adjacent lines and spaces in the mask 461 comprise varying widths. In contrast, the periodic pattern produced by the adjacent Fresnel gratings 460a and 460b comprises a plurality of higher intensity regions (e.g., the peaks in pattern 482) and a plurality of lower intensity regions (e.g., the valleys in pattern 482), wherein the widths of the plurality of peaks are substantially the same, and wherein the widths of the plurality of valleys are substantially the same, for example.

The first Fresnel grating 460a and the second Fresnel grating 460b produce an aerial image 466 of the lithography mask 461 above the support for the semiconductor device 414, (e.g., the support for the substrate 418) and the aerial image 466 of the lithography mask 461 disposed above the semiconductor device 414 produces a periodic pattern 482 comprising a sub-resolution image of the first Fresnel grating 460a and the second Fresnel grating 460b on the layer of photosensitive material 416 of the semiconductor device 414. The aerial image 466 produced by the two Fresnel gratings 460a and 460b functions as a lens that produces the periodic pattern 482 on the layer of photosensitive material 416, for example.

Advantageously, the periodic pattern 482 may comprise a sub-resolution pattern, in one embodiment. For example, the lithography system 480 may be adapted to form features having a predetermined minimum feature size, and the periodic pattern 482 may result in the formation of features comprising a size less than the minimum feature size patternable by the lithography system 480, by about 50% or more, for example. For example, if the smallest feature size patternable by the lithography system is about 75 nm, the periodic pattern 482 may comprise features having a width of about 60 nm or less. Alternatively, features comprising other dimensions relative to the resolution limit of the lithography system 480 may be patterned, for example.

The periodic pattern 482 may comprise a pattern for a plurality of lines and spaces, e.g., such as wordlines and bitlines of a memory device or other conductive lines and features of a semiconductor device. Alternatively, the periodic pattern 482 may result in the formation of other types of structures, for example. As an example, the periodic pattern 482 may be formed in an insulating material, which is then filled with a conductive or semiconductive material, e.g., in a damascene process. The periodic pattern 482 may comprise a plurality of lines and spaces having a 1:1 width ratio, although alternatively, the lines and spaces may comprise different and/or unequal dimensions, for example.

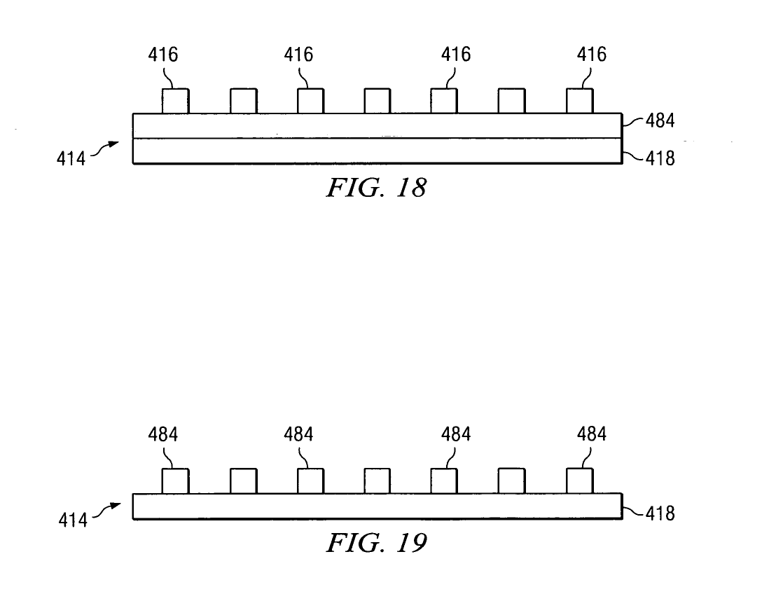

FIG. 18 shows a semiconductor substrate 414 having a layer of photoresist 416 thereon that has been patterned using the reticle 461 comprising the plurality of Fresnel gratings 460a and 460b shown in FIGS. 16 and 17. After exposure, the pattern in the layer of photoresist 416 comprises a latent pattern, which is then developed to form a pattern in the layer of photoresist 416, as shown in FIG. 18. FIG. 19 shows the semiconductor substrate of FIG. 18 after the layer of photoresist has been used to pattern a material layer 484 of the semiconductor device 414, forming sub-resolution features in the material layer 484. The layer of photoresist 416 is then removed.

Referring again to FIG. 17, in one embodiment, a method of patterning a layer of photosensitive material 416 of a semiconductor device 414 includes providing a workpiece or substrate 418, the workpiece 418 including a material layer 484 to be patterned and a layer of photosensitive material 416 disposed over the material layer 484. A lithography system 480 comprising a lithography mask 461 having at least one first Fresnel grating 460a and at least one second Fresnel grating 460b proximate the at least one first Fresnel grating 460a is provided, and the layer of photosensitive material 416 is patterned using the lithography mask 461. Patterning the layer of photosensitive material 416 preferably comprises forming a pattern for a plurality of lines and spaces on the layer of photosensitive material 416. The at least one first Fresnel grating 460a and the at least one second Fresnel grating 460b cause an interference effect of light 424 used for the patterning of the layer of photosensitive material 416, wherein the interference effect of the at least one first Fresnel grating 460a and the at least one second Fresnel grating 460b generates the pattern for the plurality of lines and spaces. The layer of photosensitive material 416 is developed, and then used as a mask to pattern the material layer 484, and the layer of photosensitive material 416 is removed.

Embodiments of the present invention also include semiconductor devices 214 and 414 patterned using the methods and lithography systems 270 and 480 described herein, for example.

Embodiments of the present invention are particularly advantageous when used in lithography systems 270 and 480 that utilize extreme ultraviolet (EUV) light, e.g., at a wavelength of about 13.5 nm, for example. Embodiments of the present invention are also advantageous when used in deep ultraviolet (DUV) lithography systems 270 and 480, immersion lithography systems 270 and 480, or other lithography systems 270 and 480 that use visible light for illumination, as example. Embodiments of the present invention may be implemented in lithography systems, steppers, scanners, step-and-scan exposure tools, or other exposure tools, as examples. The embodiments described herein are implementable in lithography systems 270 and 480 that use both refractive and reflective optics and for lenses with high and low NAs.

Embodiments of the present invention may be implemented using lithography masks 261, 361, or 461 comprising opaque or light-absorbing regions 262 or 462 and transparent or light-reflecting regions 264 or 464. Embodiments of the present invention may also be implemented in alternating phase-shift masks, combinations thereof with masks comprising opaque or light-absorbing regions 262 or 462 and transparent or light-reflecting regions 264 or 464, and other types of lithography masks, for example.

The masks 261, 361, or 461 described herein may comprise a substantially transparent material 264 or 464 comprising quartz glass having a thickness of about ¼″, with an opaque material 262 or 462 such as chromium, which is opaque, having a thickness of about 30 nm bonded to the quartz glass. Alternatively, the material 262 or 462 may comprise about 70 nm of a translucent material such as molybdenum silicon (MoSi), or a bilayer of tantalum and silicon dioxide (Ta/SiO₂). The masks 261, 361, or 461 may also be comprised of multiple layers of silicon and molybdenum to form a reflecting surface and with an absorber material of tantalum nitride (TaN), for example. Alternatively, other materials and dimensions may also be used for the transparent or light-reflecting material 264 or 464 and the opaque or light-absorbing material 262 or 462 of the masks 261, 361, or 461 described herein, for example.

Features of semiconductor devices patterned using the novel lithography reticles 461, lithography systems 480, and methods of patterning described herein may comprise transistor gates, conductive lines, vias, capacitor plates, and other features, as examples. Embodiments of the present invention may be used to pattern features of memory devices, logic circuitry, and/or power circuitry, as examples, although other types of ICs may also be fabricated using the novel lithography reticles 461, lithography systems 480, and patterning methods described herein.

Advantages of embodiments of the present invention include providing novel structures 261 and 361 and methods for testing and metrology of illuminators 202 of lithography systems. A Fresnel lens 260 or 360 is used to image the pupil fill of an exposure tool. The Fresnel lens 260 or 360 may be designed so that the lens is capable of imaging the illuminator 202 of an exposure tool within the restricted range of motion of the reticle and wafer stages, so that the image is resolved on a layer of photoresist 216.

The Fresnel lens may be used to control the focal length for capturing the source image, so that an additional mechanism such as an aperture plate is not needed to offset the Fresnel lens from the reticle plane. As an example, an aperture plate is needed in pinhole lens cameras to offset the pinhole lens from a reticle plane in order to capture the image. Thus, embodiments of the present invention provide lithography systems 270 and 480 with a reduced number of components.

Advantages of other embodiments of the present invention include providing novel lithography masks 461, lithography systems, 480 and methods for patterning periodic features having sub-resolution dimensions, such as the features formed in material layer 484 shown in FIG. 19. Thus, advantageously, embodiments of the present invention provide methods of forming features for semiconductor devices 414 that are smaller than the resolution limit of the projection lens system 410 of the lithography system 480.

Although embodiments of the present invention and their advantages have been described in detail, it should be understood that various changes, substitutions and alterations can be made herein without departing from the spirit and scope of the invention as defined by the appended claims. For example, it will be readily understood by those skilled in the art that many of the features, functions, processes, and materials described herein may be varied while remaining within the scope of the present invention. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A lithography system, comprising:
a support for a substrate;
a projection lens system;
an illuminator adapted to direct light towards the support for the substrate through the projection lens system along an optical path; and
at least one Fresnel element disposed in the optical path.

2. The lithography system according to claim 1, wherein the at least one Fresnel element comprises a Fresnel lens or a plurality of Fresnel gratings.

3. The lithography system according to claim 1, wherein the lithography system is adapted to pattern a layer of photosensitive material disposed on the substrate.

4. The lithography system according to claim 1, wherein the at least one Fresnel element is adapted to be used for metrology of the illuminator of the lithography system.

5. The lithography system according to claim 1, wherein the lithography system comprises a deep ultraviolet (DUV) lithography system, an extreme ultraviolet (EUV) lithography system, or an immersion lithography system.

6. A lithography system, comprising:
a support for a semiconductor substrate having a layer of photosensitive material disposed thereon;
a projection lens system;
an illuminator adapted to direct light towards the support for the semiconductor substrate through the projection lens system along an optical path; and
a lithography mask disposed between the illuminator and the projection lens system, the lithography mask comprising a first Fresnel grating and a second Fresnel grating proximate the first Fresnel grating.

7. The lithography system according to claim 6, wherein the first Fresnel grating and the second Fresnel grating of the lithography mask are adapted to produce a periodic pattern on the layer of photosensitive material disposed on the semiconductor substrate.

8. The lithography system according to claim 7, wherein the periodic pattern comprises a sub-resolution pattern.

9. The lithography system according to claim 7, wherein the periodic pattern comprises a pattern for a plurality of lines and spaces.

10. The lithography system according to claim 6, wherein the first Fresnel grating and the second Fresnel grating of the lithography mask produce an aerial image of the lithography mask above the support for the semiconductor substrate, and wherein the aerial image of the lithography mask produces a sub-resolution image of the first Fresnel grating and the second Fresnel grating on the layer of photosensitive material disposed on the semiconductor substrate.

11. A reticle for a lithography system, comprising:
an opaque or light-absorbing material; and
at least one Fresnel element disposed within the opaque or light-absorbing material.

12. The reticle according to claim 11, wherein the at least one Fresnel element comprises a plurality of concentric transparent or light-reflecting rings formed within the opaque or light-absorbing material, wherein each transparent or light-reflecting ring has a different width than an adjacent transparent ring.

13. The reticle according to claim 11, wherein the at least one Fresnel element comprises an array of a plurality of Fresnel lenses.

14. The reticle according to claim 11, wherein the at least one Fresnel element comprises a plurality of concentric rings having a radius r defined by Equation 8:
rₙ²≅nλf₃ Equation 8
wherein n is a number of the plurality of concentric rings, where λ is a wavelength of light used to illuminate the reticle, and wherein f₃ is the focal point away from an aerial image producible by the at least one Fresnel element.

15. A lithography system including the reticle according to claim 11, wherein when light is passed from an illuminator through the at least one Fresnel element, an image of the light from the illuminator is reproducible on a layer of photosensitive material on a semiconductor substrate, and wherein the image indicates alignment of at least one component of the illuminator or an illumination setting of the illuminator.

16. The lithography system according to claim 15, wherein the lithography system includes a projection lens system comprising an entrance pupil, wherein a first focal length is disposed between the entrance pupil and an aerial image of the light from the illuminator produced by the reticle, wherein a second focal length is disposed between the aerial image of the light from the illuminator and the layer of photosensitive material, and wherein the second focal length is less than the first focal length.

17. A method of patterning a layer of photosensitive material of a semiconductor device, the method including:
providing a workpiece, the workpiece including a material layer to be patterned and a layer of photosensitive material disposed over the material layer;
providing a lithography system comprising a lithography mask having at least one first Fresnel grating and at least one second Fresnel grating proximate the first Fresnel grating; and
patterning the layer of photosensitive material using the lithography mask.

18. The method according to claim 17, wherein patterning the layer of photosensitive material comprises forming a pattern for a plurality of lines and spaces on the layer of photosensitive material, wherein the at least one first Fresnel grating and the at least one second Fresnel grating cause an interference effect of light used for the patterning of the layer of photosensitive material, and wherein the interference effect of the at least one first Fresnel grating and the at least one second Fresnel grating generates the pattern for the plurality of lines and spaces.

19. The method according to claim 17, further comprising using the layer of photosensitive material as a mask to pattern the material layer of the workpiece, and removing the layer of photosensitive material.

20. The method according to claim 19, wherein the material layer of the workpiece comprises a conductive material, an insulating material, a semiconductive material, or multiple layers or combinations thereof.

21. A semiconductor device manufactured in accordance with the method of claim 19.

22. A metrology method, comprising:
providing a workpiece, the workpiece including a layer of photoresist formed thereon;
disposing a test reticle having a Fresnel element disposed thereon between the illuminator and a projection lens system of the lithography system;
illuminating the layer of photoresist with light from the illuminator;
developing the layer of photoresist; and
examining the layer of photoresist to determine if a component of the lithography system requires adjusting.

23. The method according to claim 22, wherein the lithography system includes an illuminator, wherein an image formed on the layer of photoresist comprises at least one circular shape corresponding to the shape of a source of the illuminator, and a ring proximate the at least one circular shape corresponding to a numerical aperture of the illuminator.

24. The method according to claim 22, wherein the illuminator comprises a source, an integrator, and a condenser lens, further comprising adjusting the source, integrator, and/or condenser lens after examining the layer of photoresist, or adjusting an illumination setting of the illuminator.

25. The method according to claim 22, wherein the Fresnel element blocks even or odd diffracted orders of the light.
